(19) United States
(12) Patent Application Publication
(10) Pub. No.: US 2022/0171105 A1
(43) Pub. Date: Jun. 2, 2022

(54) RESONANT FILTERS HAVING SIMULTANEOUSLY TUNED CENTRAL WAVELENGTHS AND SIDEBANDS

(71) Applicant: Board of Regents, The University of Texas System, Austin, TX (US)

(72) Inventors: Yeong Hwan Ko, Grand Prairie, TX (US); Neelam Gupta, Bethesda, MD (US); Robert Magnusson, Arlington, TX (US)

(21) Appl. No.: 17/471,717

(22) Filed: Sep. 10, 2021

Related U.S. Application Data
(60) Provisional application No. 63/077,213, filed on Sep. 11, 2020.

(51) Int. Cl. G02B 5/18; G03F 7/00

(52) U.S. Cl. CPC G02B 5/1814; G03F 7/0007; G02B 5/1857

(57) ABSTRACT

A tunable optical filter comprises a resonant grating layer having an aperiodic pattern, an optional sublayer, a waveguide layer, and a substrate layer, wherein at least one of the waveguide layer and the sublayer, when present is inhomogenous. In some instances, the optional sublayer and/or the waveguide layer may comprise a thickness gradient. Incident light may be filtered and/or reflected by an optical filter, for instance a band of incident electromagnetic radiation has 90% or greater transmittance or reflectance and adjacent bands of incident electromagnetic radiation have 10% or less transmittance or reflectance, respectively.

### RELATED APPLICATION DATA

This application claims priority under 35 U.S.C. § 119(e) to U.S. Provisional Patent Application No. 63/077,213 filed Sep. 11, 2020, the entirety of which is incorporated by reference herein.

### STATEMENT REGARDING GOVERNMENT FUNDING

This invention was made with government support under contract nos. W911NF-15-2-0092 and W911NF-19-2-0171 awarded by the U.S. Army Research Laboratory. The government has certain rights in the invention.

### FIELD

The technology described herein generally relates to optical filters, more specifically to tunable resonant filters having concurrently tuned central wavelengths and sidebands.

### BACKGROUND

Multilayer dielectric thin films are widely applied to implement metal-free and low-loss filters, polarizers, and reflectors for incorporation in various optical systems. These elements or devices generally consist of stacks of homogeneous layers of films deposited with precise thicknesses and tight control of index of refraction and absorption. In many cases, a large number of layers, for instance ˜10-100, may be needed to create the spectral attributes required for a particular application. These optical devices operate on the basis of multiple reflections that occur between the interfaces incorporated into a layered stack that make up the optical device. Some multilayer systems, such as quarter-wave layer systems, typically provide the low transmission sidebands whereas an inclusion of a defect layer, such as a half-wave layer, provides the transmission peak. It will be appreciated that numerous thin-film filter designs can be achieved with intermingling of quarter-wave thick, half-wave thick, and arbitrary thickness films.

Practical issues in thin-film manufacturing include adhesion difficulties associated with forming the multilayered stacks as well as losses inherently associated with multilayered arrangements. Delamination failures under thermal expansion and high-power laser irradiation can occur.

In contrast to conventional thin-film filters, the technology described herein generally relates to tunable filters that have minimal material embodiments as compared to known filters. In particular, guided-mode resonance (GMR) filters can render a desired spectral response through particular design elements via their structural parameters including period, fill factor, grating depth, and spatial modulation strength by choice of materials and modulation. For many applications, high-quality filters require rectangular spectra with flat tops, steep-slope drop-off, and low sidebands all while retaining high efficiency.

### SUMMARY

This summary is provided to introduce a selection of concepts in a simplified form that are further described below in the detailed description. This summary is not intended to identify key features or essential features of the claimed subject matter, nor is it intended to be used in isolation as an aid in determining the scope of the claimed subject matter.

Embodiments of the technology described herein are generally directed towards efficient filters, more particularly tunable resonant filters that have simultaneously tuned central wavelengths and sidebands. Tunable optical elements, or resonant filters, described herein provide alternatives/improvements over traditional tunable elements. Such tunable filters incorporate spatially inhomogenous films that achieve favorable filtering characteristics. In some particular instances, the optical filters achieve good efficiency in the long-wave infrared (LWIR) spectral region

According to some embodiments, a tunable optical filter is provided. An optical filter can comprise a resonant grating layer having a periodic or aperiodic pattern, a sublayer, a waveguide layer, and a substrate later. In some instances, at least one of the waveguide layer and the sublayer, when present, can be inhomogenous. Moreover, it is to be understood that the various layers of an optical filter or device described herein can have differing refractive indices. For example, the waveguide layer can have a refractive index differing from the refractive index of one or more (or all) of the immediately adjacent layers.

According to some further embodiments, a method of fabricating a tunable optical filter is provided. An aperiodic grating pattern can be determined for a resonant grating layer, and a thickness gradient can be determined for a waveguide layer and optionally a grating sublayer. A waveguide layer can then be deposited onto a substrate corresponding to the thickness of the determined waveguide layer. A thin film can be deposited onto the waveguide layer and subsequently, a resonant grating layer can be generated or otherwise formed in at least a portion of the thin film layer corresponding to the determined aperiodic grating pattern.

According to some even further embodiments, a method of transmitting and/or reflecting light via an optical element is provided. An incident electromagnetic wave can be received at a tunable optical filter. A first band of the incident electromagnetic radiation can be transmitted through or reflected by the tunable optical filter and adjacent bands to the first band of the incident electromagnetic radiation can be transmitted through or reflected by the tunable optical filter. In some instances, the tunable optical filter can exceed 90% in peak reflectance and less than or equal to 10% in adjacent band reflectance.

Additional objects, advantages, and novel features of the technology will be set forth in part in the description which follows, and in part will become apparent to those skilled in the art upon examination of the following, or can be learned by practice of the invention.

### BRIEF DESCRIPTION OF THE DRAWINGS

Aspects of the technology presented herein are described in detail below with reference to the accompanying drawing figures, wherein:

FIG. 1A shows a schematic model of a resonant periodic device, in accordance with some aspects of the technology described herein;

FIG. 1B shows a schematic model of a resonant periodic device, in accordance with some aspects of the technology described herein;

FIG. 2A illustrates a schematic of an example optical element, in accordance with some aspects of the technology described herein;

FIG. 2B illustrates a schematic and modeling of an example optical element, in accordance with some aspects of the technology described herein;

FIG. 2C illustrates a schematic and modeling of an example optical element, in accordance with some aspects of the technology described herein;

FIG. 3A shows a schematic of an example optical element and spectral response analysis thereof, in accordance with some aspects of the technology described herein;

FIG. 3B shows a spectral response analysis of an example optical element, in accordance with some aspects of the technology described herein;

FIG. 3C shows a spectral response analysis of an example optical element, in accordance with some aspects of the technology described herein;

FIG. 4A illustrates tunability of an optical element in accordance with some aspects of the technology described herein;

FIG. 4B illustrates tunability of an optical element in accordance with some aspects of the technology described herein;

FIG. 4C illustrates tunability of an optical element in accordance with some aspects of the technology described herein;

FIG. 5A illustrates realization of wide tunable sidebands of an optical element in accordance with some aspects of the technology described herein;

FIG. 5B illustrates realization of wide tunable sidebands of an optical element in accordance with some aspects of the technology described herein;

FIG. 6A illustrates an example tunable GMR filter with nonperiodic ZCG on an inhomogenous waveguide, in accordance with some aspects of the technology described herein;

FIG. 6B illustrates an example tunable GMR filter with nonperiodic ZCG on an inhomogenous waveguide, in accordance with some aspects of the technology described herein;

FIG. 6C illustrates an example tunable GMR filter with nonperiodic ZCG on an inhomogenous waveguide, in accordance with some aspects of the technology described herein;

FIG. 7A illustrates polarization independent optical elements, in accordance with some aspects of the technology described herein;

FIG. 7B illustrates polarization independent optical elements, in accordance with some aspects of the technology described herein;

FIG. 7C illustrates polarization independent optical elements, in accordance with some aspects of the technology described herein;

FIG. 8A illustrates example methods of designing optical elements, in accordance with some aspects of the technology described herein;

FIG. 8B illustrates example methods of designing optical elements, in accordance with some aspects of the technology described herein;

FIG. 9A illustrates fabrication of aperiodic optical filters, in accordance with some aspects of the technology described herein;

FIG. 9B illustrates fabrication of aperiodic optical filters, in accordance with some aspects of the technology described herein;

FIG. 10 illustrates tuning optical filters, in accordance with some aspects of the technology described herein;

FIG. 11A illustrates a tunable notch filter, in accordance with some aspects of the technology described herein;

FIG. 11B illustrates a tunable notch filter, in accordance with some aspects of the technology described herein;

FIG. 12A illustrates an analysis of a GMR location generated by a ZCG structure, in accordance with some aspects of the technology described herein;

FIG. 12B illustrates an analysis of a GMR location generated by a ZCG structure, in accordance with some aspects of the technology described herein;

FIG. 12C illustrates an analysis of a GMR location generated by a ZCG structure, in accordance with some aspects of the technology described herein;

FIG. 13A illustrates the fabrication of a nonperiodic grating relating to an optical element, in accordance with some aspects of the technology described herein;

FIG. 13B illustrates the fabrication of a nonperiodic grating relating to an optical element, in accordance with some aspects of the technology described herein;

FIG. 14A illustrates spectra relating to a nonperiodic optical element, in accordance with some aspects of the technology described herein;

FIG. 14B illustrates spectra relating to a nonperiodic optical element, in accordance with some aspects of the technology described herein;

FIG. 15A illustrates a design for expanding an optical filter tunable range, in accordance with some aspects of the technology described herein;

FIG. 15B illustrates a design for expanding an optical filter tunable range, in accordance with some aspects of the technology described herein;

FIG. 16A illustrates modeling of a ZCG structure relating to an optical element, in accordance with some aspects of the technology described herein;

FIG. 16B illustrates modeling of a ZCG structure relating to an optical element, in accordance with some aspects of the technology described herein;

FIG. 16C illustrates modeling of a ZCG structure relating to an optical element, in accordance with some aspects of the technology described herein;

FIG. 17A illustrates a serial device relating to a GMR filter, in accordance with some aspects of the technology described herein;

FIG. 17B illustrates a serial device relating to a GMR filter, in accordance with some aspects of the technology described herein;

FIG. 18A illustrates the fabrication and measurement of a grating relating to an optical element, in accordance with some aspects of the technology described herein;

FIG. 18B illustrates the fabrication and measurement of a grating relating to an optical element, in accordance with some aspects of the technology described herein;

FIG. 18C illustrates the fabrication and measurement of a grating relating to an optical element, in accordance with some aspects of the technology described herein;

FIG. 19 shows a measurement setup for a serial element with a varying polarization angle, in accordance with some aspects of the technology described herein;

FIG. 20A shows an unpolarized spectral response of a serial device, in accordance with some aspects of the technology described herein;

FIG. 20B shows an unpolarized spectral response of a serial device, in accordance with some aspects of the technology described herein;

FIG. 21A illustrates the modeling of a ZCG on a waveguide structure, in accordance with some aspects of the technology described herein;

FIG. 21B illustrates the modeling of a ZCG on a waveguide structure, in accordance with some aspects of the technology described herein;

FIG. 21C illustrates the modeling of a ZCG on a waveguide structure, in accordance with some aspects of the technology described herein;

FIG. 22A illustrates an analysis of spectral responses of a ZCG waveguide design, in accordance with some aspects of the technology described herein;

FIG. 22B illustrates an analysis of spectral responses of a ZCG waveguide design, in accordance with some aspects of the technology described herein;

FIG. 22C illustrates an analysis of spectral responses of a ZCG waveguide design, in accordance with some aspects of the technology described herein;

FIG. 23A illustrates tenability of a chirped ZCG on a waveguide of an optical element, in accordance with some aspects of the technology described herein;

FIG. 23B illustrates tenability of a chirped ZCG on a waveguide of an optical element, in accordance with some aspects of the technology described herein;

FIG. 23C illustrates tenability of a chirped ZCG on a waveguide of an optical element, in accordance with some aspects of the technology described herein;

FIG. 24A illustrates expansion of tunable sidebands relating to an optical element, in accordance with some aspects of the technology described herein;

FIG. 24B illustrates expansion of tunable sidebands relating to an optical element, in accordance with some aspects of the technology described herein;

FIG. 25A illustrates a tunable GMR filter with a chirped ZCG on an inhomogenous waveguide, in accordance with some aspects of the technology described herein;

FIG. 25B illustrates a tunable GMR filter with a chirped ZCG on an inhomogenous waveguide, in accordance with some aspects of the technology described herein; and

FIG. 25C illustrates a tunable GMR filter with a chirped ZCG on an inhomogenous waveguide, in accordance with some aspects of the technology described herein.

### DETAILED DESCRIPTION

The subject matter of aspects of the present disclosure is described with specificity herein to meet statutory requirements. However, the description itself is not intended to limit the scope of this patent. Rather, the inventors have contemplated that the claimed subject matter might also be embodied in other ways, to include different steps or combinations of steps similar to the ones described in this document, in conjunction with other present or future technologies. Moreover, although the terms “step” and/or “block” can be used herein to connote different elements of methods employed, the terms should not be interpreted as implying any particular order among or between various steps disclosed herein unless and except when the order of individual steps is explicitly described.

Accordingly, embodiments described herein can be understood more readily by reference to the following detailed description, examples, and figures. Elements, apparatus, and methods described herein, however, are not limited to the specific embodiments presented in the detailed description, examples, and figures. It should be recognized that the exemplary embodiments herein are merely illustrative of the principles of the invention. Numerous modifications and adaptations will be readily apparent to those of skill in the art without departing from the spirit and scope of the invention.

In addition, all ranges disclosed herein are to be understood to encompass any and all subranges subsumed therein. For example, a stated range of “1.0 to 10.0” should be considered to include any and all subranges beginning with a minimum value of 1.0 or more and ending with a maximum value of 10.0 or less, e.g., 1.0 to 5.3, or 4.7 to 10.0, or 3.6 to 7.9.

All ranges disclosed herein are also to be considered to include the end points of the range, unless expressly stated otherwise. For example, a range of “between 5 and 10” or “5 to 10” or “5-10” should generally be considered to include the end points 5 and 10.

Further, when the phrase “up to” is used in connection with an amount or quantity; it is to be understood that the amount is at least a detectable amount or quantity. For example, a material present in an amount “up to” a specified amount can be present from a detectable amount and up to and including the specified amount.

Additionally, in any disclosed embodiment, the terms “substantially,” “approximately,” and “about” may be substituted with “within [a percentage] of” what is specified, where the percentage includes 0.1, 1, 5, and 10 percent.

Tunable visible and infrared (IR) filters are important for various optical and optoelectronic systems. Ideally, the tunable filters should span wide spectral ranges with low sidebands while retaining constant spectral performance. According to the technology described herein, highly tunable resonant filters with excellent and practical total performance are provided. In some example embodiments, a tunable optical filter comprises a nonperiodic grating and inhomogeneous subfilm, which enable resonant tunable filters for operation in the ˜5-14 μm band. As central wavelength is tuned, adjacent filter sidebands are concurrently tuned to achieve final high-quality filter characteristics. This can be expanded to other spectral regions including the visible, near-IR, mid-IR, and terahertz (THz) regions.

Resonant filters and/or reflectors, for instance wideband resonant filters, can be designed with gratings in which the grating ridges are matched to an identical material, thus eliminating local reflections and phase changes. The critical interface possesses zero-refractive index contrast, and is known as a zero-contrast grating (ZCG).

Described herein are optical elements, more particularly highly tunable resonant filters, and methods for their design, fabrication, and implementation that exhibit good spectral filtering profiles across wide frequency bands which are needed in a variety of optical applications. Generally, the tunable resonant filters described herein incorporate aperiodic gratings and inhomogenous subfilms, for instance, films that are incorporated into an optical element can have a gradient or varying thickness across their length and/or width. In some aspects, the tunable resonant filters include features that utilize guided-mode resonance (GMR) effects, for instance in spatially aperiodic films and film structures.

According to some embodiments tunable optical filters are provided. In some instances, a tunable optical filter may be composed of a plurality of layers, which may include a grating layer (e.g. resonant grating layer), a grating sublayer, a waveguide layer, and a substrate layer. In some instances, a grating sublayer is optionally present. In some embodiments, the sublayer and/or the waveguide layer can be inhomogenous, that is, a layer can vary in thickness across the length and/or width of the optical element. A variation in thickness can be, for example, presented as a thickness gradient across the length and/or width of a surface of a layer of the optical element. For example, an inhomogenous layer can have a thickness gradient along the length and/or width of the top surface of a layer of the optical filter, including the gradient layer. In some instances, an inhomogenous layer can have a first thickness gradient along the length of a top surface of a layer of the optical filter, and a second thickness gradient along the width of a top surface of a layer of the optical filter.

A tunable optical filter can transmit, reflect, absorb, and/or block electromagnetic radiation (i.e. wavelengths), for instance a tunable optical filter can transmit and/or reflect a first band of electromagnetic radiation and additionally transmit, reflect, absorb, and/or block adjacent bands of electromagnetic energy (in some instances referred to as sidebands). According to some aspects, an optical filter can be tuned to achieve >90% peak reflectance and <10% adjacent band or sideband reflectance. In some other embodiments, an optical filter can have >95%, >98%, or >99% peak reflectance of a first band of electromagnetic radiation. In some other aspects, an optical filter can have <5% adjacent band reflectance. A grating, such as a resonant grating, can have a periodic or an aperiodic (i.e. nonperiodic) pattern, and additionally, a grating can have a one-dimensional (1D) or two-dimensional (2D) periodic and/or aperiodic pattern. In some additional embodiments, an optical filter may comprise additional layers and/or coatings, such as anti-reflective coatings which may, for example be applied to a surface of any of the layers, for instance a surface of the substrate layer.

According to various embodiments, the layers of an optical filter can be composed of any materials not inconsistent with objectives described herein. In some instances, a grating layer can be formed from Si₃N₄, TiO₂, ZnO, ZnSe, ZnS, Si, Ge, epoxy, or fiberglass, among other materials. A sublayer, for instance a grating sublayer, can be formed from Si₃N₄, TiO₂, ZnO, ZnSe, ZnS, Si, or Ge, among other materials. A waveguide layer can be formed from Si₃N₄, TiO₂, ZnO, ZnSe, ZnS, Si, or Ge, among other materials. A substrate, or substrate layer, can be formed from a chalcogenide glass (e.g. GeₓAs_{y}Se_{1-x-y}, GeₓSb_{y}Se_{1-x-y}, As₄Se₆, As₂S₃), ZnSe, ZnS, Si, Ge, silica, or quartz, among other materials.

In some further embodiments, a method of fabricating a tunable optical filter is provided. According to various embodiments, methods of fabricating a tunable filter or optical element comprises determining a periodic or aperiodic grating pattern for a grating layer, such as a resonant grating layer, determining a thickness gradient for a waveguide layer and optionally a thickness gradient for a grating sublayer, depositing the waveguide layer onto a substrate corresponding to the determined thickness of the waveguide layer, depositing a thin film layer onto the waveguide layer, and subsequently generating a grating (e.g. a 1D or 2D grating pattern), for instance a resonant grating pattern, in at least a portion of the thin film layer corresponding to the determined grating pattern (e.g. an aperiodic grating pattern). A periodic and/or aperiodic grating pattern can be formed as a 1D or 2D periodic or aperiodic pattern. Accordingly, in some instances, generating a resonant grating layer can form the resonant grating layer and an optional grating sublayer. In some other instances, the resonant grating layer can be formed directly on top of a waveguide layer and as such the optional grating sublayer is not formed. In some embodiments, the waveguide layer and/or the thin film layer may be coated onto a substrate by thin-film deposition.

A method of fabricating a tunable optical filter may also, in some instances, comprise determining a grating pattern (e.g. an aperiodic grating pattern) for the resonant grating layer and determining the thickness gradient for the waveguide layer, and further optionally determining a thickness gradient for a grating sublayer by selecting a specified wavelength transmission or reflectance band with respect to the grating or overall optical element.

In some further embodiments, the periodic or aperiodic grating layer may be generated by providing a photoresist film disposed on the thin film layer, exposing the photoresist film with an interference pattern corresponding to the grating pattern (e.g. the periodic or aperiodic grating pattern) and transferring the grating pattern to at least a portion of the thin film layer.

In some additional embodiments, the method may comprise depositing additional layers and/or coatings onto one or more layers of an optical filer or resonant filer, such as anti-reflective coatings which may, for example be applied to a surface of any of the layers, for instance a surface of the substrate layer.

In some embodiments according to the technology described herein, a method of transmitting and/or reflecting light is provided. A method of transmitting and/or reflecting light may comprise receiving an incident electromagnetic wave (e.g. a light wave) at a tunable optical filter, for instance at an optical filter described herein. A first band of incident electromagnetic radiation can be transmitted through and/or reflected by the tunable optical filter and adjacent bands to the first band of incident electromagnetic radiation may be transmitted through and/or reflected by the tunable optical filter. Methods of filtering may include transmitting, reflecting, absorbing, and/or blocking a first band of electromagnetic radiation (i.e. wavelengths) and further transmitting, reflecting, absorbing, and/or blocking adjacent bands of electromagnetic energy (in some instances referred to as sidebands). Methods according to the present technology can include achieving >90% peak reflectance and <10% adjacent band or sideband reflectance. In some other embodiments, a method may include reflecting >95%, >98%, or >99% of incident light (e.g. a first band of electromagnetic radiation) and further reflecting <5% of an adjacent band of incident light.

Incident electromagnetic waves as described herein can include visible light, infrared (IR) light, THz frequency light, and/or microwave light. Additionally, a first band of an incident electromagnetic wave can include visible light, infrared (IR) light, THz frequency light, and/or microwave light. An incident electromagnetic wave can be at normal or non-normal incidence, and further have a polarization state of at least one of random, unpolarized, linear, circular, and/or elliptical.

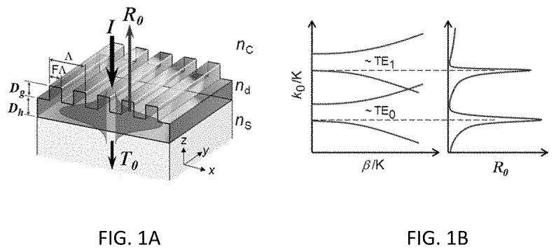

Turning now to the figures, in some embodiments tunable optical filters, such as tunable resonant filters, can be implemented with periodic or aperiodic gratings, for instance a periodic or aperiodic zero-contrast grating (ZCG). Referring to FIGS. 1A-B, a schematic and modeling of a resonant device in accordance with some embodiments of the present technology is illustrated. FIG. 1A shows a one dimensional (1D) resonant periodic device having a ZCG where grating ridges are matched to a sublayer made out of the same material, and consequently no phase changes occur for a ridge mode transiting across the ridge/sublayer interface. In accordance with FIG. 1A, a two-layer element architecture is shown for a component resonant grating, in particular a view of a subwavelength periodic element under normal incidence. The two-layer element can have thicknesses D_{g} and Dₕ, fill factor F, and a two-part period Λ is illustrated with the refractive indices of the various regions (cover, device, substrate) denoted as n, for example n_{c}, n_{d}, and nₛ. When phase matching occurs between evanescent diffraction orders and a waveguide mode, a reflection resonance takes place. I, R₀, and T₀ denote the incident wave with wavelength λ and the zero-order reflectance and transmittance, respectively. Under normal incidence, counter-propagating leaky modes form a standing wave in the device as indicated in FIG. 1A. As the modes interact with the waveguide grating, they re-radiate reflectively. Turning to FIG. 1B, a schematic of a dispersion diagram is shown. The device works in the second stop band corresponding to the second-order grating. A given evanescent diffraction order can excite not just one but several leaky modes. To emphasize this point, FIG. 1B shows the stop bands for the first two transverse electric (TE) modes. At each stop band, a resonance is generated as denoted in FIG. 1B. The fields radiated by these leaky modes in a grating with a symmetric profile can be in phase or out of phase at the edges of the band. At one edge, there is a zero phase difference, and hence the radiation is enhanced while at the other edge, there is a π phase difference inhibiting the radiation. In this case, if β=β_{R}+iβ_{I} is the complex propagation constant of the leaky mode, then β_{I}=0 at one edge, which implies that no leakage is possible at that edge. For asymmetric grating profiles, there is a resonance at each band edge. Spectral characteristics and local fields of GMR devices can be expeditiously quantified with exact numerical methods, for example, with rigorous coupled-wave analysis (RCWA) computer codes. Referring again to FIG. 1B, dispersion diagram of a subwavelength grating at the second stop band is shown. For the symmetric grating profile, a resonance appears at one edge. This schematic applies to both TE (electric field vector normal to the plane of incidence and parallel to the y-direction) and TM (magnetic field vector normal to the plane of incidence and parallel to the y-direction) polarization states. Here, the grating vector has magnitude K=2π/Λ, the wavenumber of the input wave is k₀=2π/λ, and β is the propagation constant of a leaky mode.

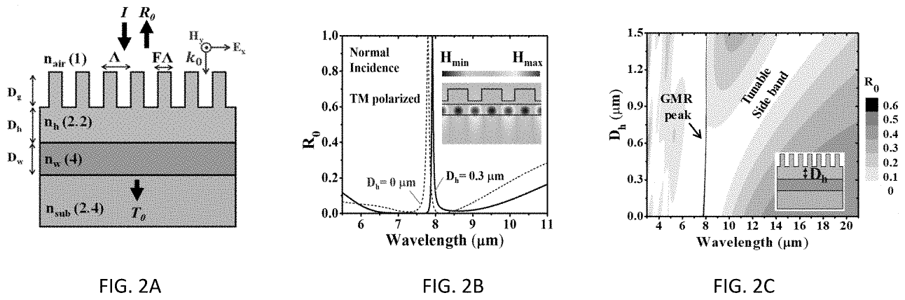

Guided-mode resonance (GMR) in as effect in optical physics wherein the guided modes of an optical waveguide can be excited and simultaneously extracted, re-radiated by the inclusion of a phase matching element, such as a diffraction grating, in the structure. Such modes are also called “leaky modes,” since they do not remain guided, but instead can be extracted from the waveguide. Thus, GMR effects can arise via quasi-guided or leaky waveguide modes induced on patterned films with subwavelength periods. In the design of GMR filters, desired spectral responses can be obtained through the variation of design parameters for GMR filters. Turning now to FIG. 2A, a one-dimensional (1D) ZGC on a homogenous film is illustrated. With a relatively low refractive index, the ZCG plays two important roles in GMR filters. First, the grating diffractively couples the input light to the waveguide forming a lateral guided mode. Here, the period predominantly sets the GMR location. Secondly, the sublayer of the ZCG suppresses the background reflection as a buffer layer which relieves the large difference of refractive index between the grating and the waveguide. However, for some designs, the sublayer does not significantly influence the GMR location. In accordance with the example embodiment of FIG. 2, a grating parameter set is defined {Λ=period, F=fill factor, D_{g}=grating depth, Dₕ=sublayer thickness, D_{w}=waveguide thickness}. For high diffraction efficiency operating at the long wavelength infrared (LWIR) region, ZnS (n_{ZnS}=2.2), Ge (n_{Ge}=4), and ZnSe (n_{ZnSe}=2.4) are implemented as low loss materials. It will be appreciated that these indices are dispersive with absorption such that the complex refractive index is {ñ(λ)=n(λ)+ik(λ)} in the LWIR region. In this example, within the spectral region of 3-20 μm, n is approximated as constant and assumed lossless media such that k=0. The parameter set is subsequently optimized via rigorous coupled-wave analysis (RCWA). The spectral response is calculated at normal incidence with a TM-polarization state (E-field perpendicular to the grooves) as shown in FIG. 2A. Referring to FIG. 2B, the optimized R₀ spectra for the narrowband reflection filter is shown. For the grating parameter set {Λ=2.9 μm, F=0.6, D_{g}=1 μm, Dₕ=0.3 μm, D_{w}=0.9 μm}, a TM resonance peak (R₀=100%) with a narrow band (full-width at half maximum, FWHM=48 nm) locates at 7.91 μm. For R₀<5%, the sideband is distributed from 5.96 μm to 9.65 μm. Comparing the R₀ spectrum at Dₕ=0 μm, it can be seen that the sublayer aids in suppressing the sidebands. In a view of the magnetic field (H) distribution, it can be ascertained that the GMR is generated by first-order evanescent diffraction coupled to the waveguide. Referring now to FIG. 2C, the Dₕ dependent R₀ spectra are featured in a gray-scale contour map. As Dₕ increases, the GMR peak position moves to slightly longer wavelengths. In contrast, the low reflection region becomes gradually wider and red-shifted with a split. Importantly, this trend of background reflection is suitable for flexible control of the sidebands of the tunable filter. However, the GMR peak position does not follow along to the center of sideband, which can be resolved by variation of the grating period via aperiodic (i.e. nonperiodic) grating.

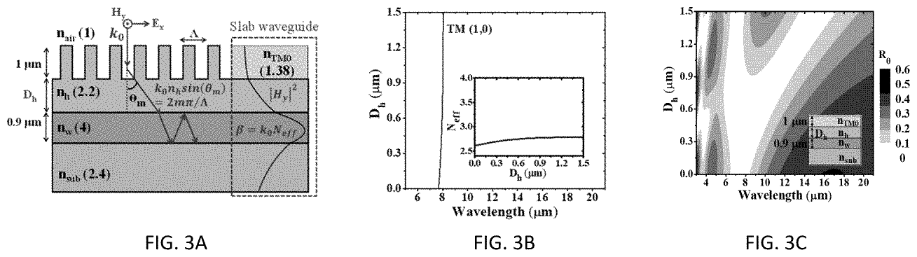

To clarify the spectral response shown in FIG. 2C, the equivalent slab waveguide and modal processes as illustrated in FIG. 3A is analyzed. For the slab waveguide, the refractive index of the top layer is estimated by zeroth-order effective medium theory in TM mode (n_{TM0}=1.38). Under normal incidence, the light passes through the ZCG with diffraction angle (θₘ) as k₀nₕ sin(θₘ)=2mπ/Λ, (m=0, 1, 2 . . . ) which is a phase matching condition. Therefore, the longitudinal component of wave vector in each layer is 2mπ/Λ. When it equals to the propagation constant of waveguide (i.e., 2mπ/Λ==k₀N_{eff}), the diffracted wave can be coupled to a waveguide mode. For the equivalent multilayer slab waveguide, the effective index of the guided mode (N_{eff}) and propagation constant (β) are obtained by a mode solver for multilayered media.

FIG. 3B illustrates the calculated GMR peak position as a function of the Dₕ which is well matched to the RCWA-computed GMR location as described with respect to FIG. 2C. In this instance, the mode is labeled as TM(m,n) when the GMR forms at the mth diffraction coupled to the nth guided mode. In this case, only TM(1,0) is generated in this spectral range. Even though the Dₕ increases substantially, the TM(1,0) position is minimally varied. In a view of the inset, it is explained by the fact that the N_{eff} varies slowly due to the low refractive index of the sublayer Dₕ. Thus, the λ_{GMR} shifts only a little. In contrast, the value of Dₕ influences the background reflection.

FIG. 3C illustrates the R₀ spectra of the corresponding multilayer where the top layer is homogenized with zero-order effective refractive index (n_{TM0}=1.38) to eliminate the GMR. The spectral characteristic is comparable to the background reflectance of FIG. 2C. As the Dₕ increases, the low reflection band expands and moves to the longer wavelengths because the buffer layer (n=2.2) between the top layer (n=1.38) and the waveguide (n=4) relieves the index difference as well as changes the spectral region of destructive interference.

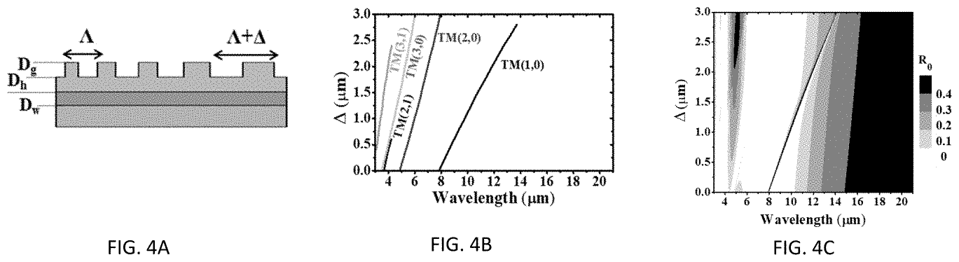

In accordance with some embodiments of the present technology, highly tunable resonant filters can be provided having aperiodic (i.e. non-periodic) grating filters for wavelength tuning. In some instances, an optical filter, or resonant filter can be implemented by GMR structures having aperiodic gratings and inhomogenous subfilms. According to the formula (2mπ/Λ=k₀N_{eff}), it is apparent that the resonant position of a filter can tuned by varying the period of the grating. Referring to FIG. 4A, an example aperiodic grating is illustrated having variation (Δ) of period (i.e. exhibiting aperodicity). In some example embodiments, the resonance wavelength λ can be tuned by laterally transferring the device relative to the illuminating wave. FIG. 4B illustrates the modal curves associated with a nonperiodic grating where the grating parameter set is {Λ=2.9 μm+Δ, F=0.6, D_{g}=1 μm, Dₕ=0.3 μm, D_{w}=0.9 μm}. As Δ increases, five GMR modes appearing in the spectral band are shown and move to longer wavelengths. In particular, the TM(1,0) mode, the only one that experiences subwavelength conditions, shifts quickly away from the other GMR modes, which is desirable to avoid interference from these channels which would generate undesired reflection peaks and transmission notches. As can be seen in FIG. 4C, this trend is also seen in the results of RCWA calculation for the same structure. As previously expected via the modal curve in FIG. 4B the primary channel appears separately from the other channels and is tuned by the variation of the period. However, the nonperiodic grating does not affect the background reflection. To implement tunable filters, therefore, an additional challenge is to concomitantly move the sidebands to effectively surround the resonance spectral peak.

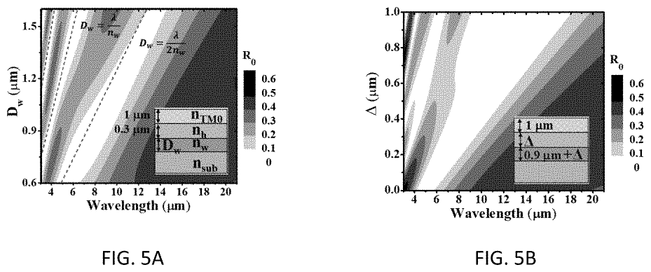

Accordingly, with respect to some other embodiments, high filtering performance across wide spectral bands can be realized through concurrent tuning of central filter wavelength and sideband spectral location of a filter or optical device. In some instances, inhomogenous subfilms can be utilized for sideband tuning, for example to find low tunable sidebands. As illustrated in FIG. 5A, the sideband moves to longer wavelengths while increasing the thickness of the waveguide layer (D_{w}). In fact, the low reflection region is mainly formed by destructive interference. In this case, the destructive interference condition is given by 2n_{w}D_{w}=qλ where q is an integer. This condition is well matched to the tunable sidebands as represented by the dashed lines shown in FIG. 5A. In order to further expand the bandwidth, a variation (Δ) is applied to D_{w} and Dₕ at the same time. FIG. 5B illustrates a corresponding result. When Δ increases, the low reflectance region expands and red shifts. This can be attributed primarily to the increase of the buffer layer thickness (Dₕ).

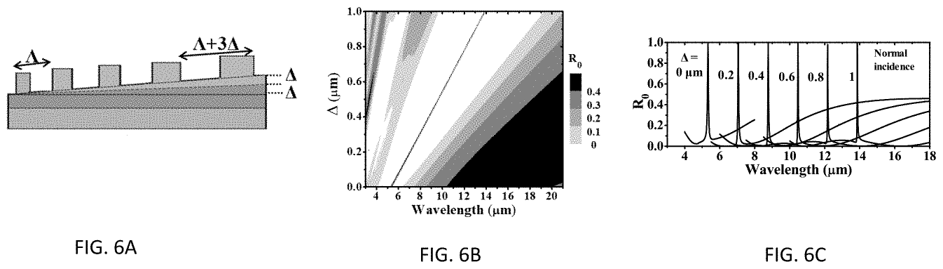

Referring now to FIG. 6A, in accordance with the present technology, a tunable GMR filter having an aperiodic ZGC on an inhomogenous (i.e. wedged) structure is illustrated. In order to match the tunable position of the GMR peak (λ_{GMR}) to the center of the sideband each shift rate (δλ_{GMR}/Δ, λλ_{side}/Δ) per the variation (Δ) is considered. As seen in FIGS. 4C and 5B, the shift rates of the nonperiodic grating and wedged structure are found as 7.26 and 2.11, respectively, which means that λ_{GMR} tunes 3.43 times faster than λ_{side} for the same variation. In this representative example, considering the GMR peak shift affected by the variation in the wedged structure, a factor 3 between the nonperiodic grating and wedged structure is determined which then gives the grating parameter set as {Λ=2 μm+3Δ, F=0.6, D_{g}=1 μm, Dₕ=Δ, D_{w}=0.9 μm+Δ}. FIG. 6B illustrates the R₀ map of the resultant structure, showing that the primary channel locates at the center of the sideband. As Δ increases up to 1 μm, the GMR peak gradually shifts from 5.3 to 14 μm. In view of the individual R₀ plots in FIG. 6C, this indicates that tunable filters with this, or similar, architecture can attain high diffraction efficiency with well-shaped spectra. As can be seen when Δ=0 μm, the sidebands are high, owing to the high-contrast grating without a sublayer. Above the Δ=0.2 μm level, the sidebands retain low reflection mediated by the homogeneous buffer layer with thickness (Dₕ) in the ZCG.

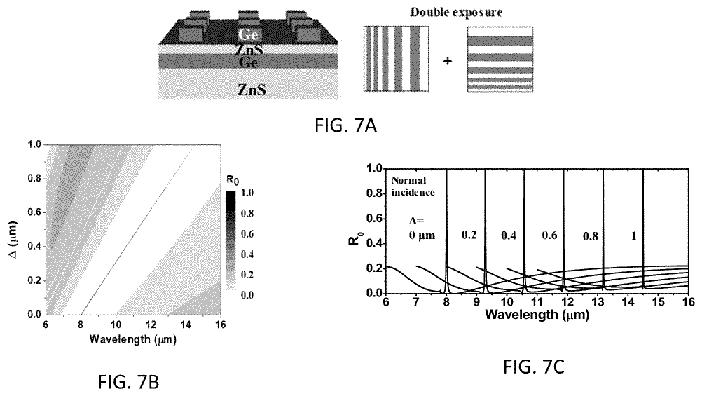

In some other example embodiments, polarization independent filters are provided. Turning to FIG. 7A, polarization independent tunable filters achieved by employing 2D GMR structures is illustrated. At normal incidence, the tunability property is retained regardless of polarization of the input beam. The nonperiodic 2D grating can be fabricated by a double-exposure lithography process with line-patterned mask. In the same way as provided for 1D GMR filters, the 2D grating parameters are determined by RCWA. As a result, an example grating parameter set is {Λ=3.5 μm+3Δ, F=0.45, D_{g}=0.65 μm (Ge), Dₕ=0.85 μm+Δ (ZnS), D_{w}=0.15 μm (Ge)}. As illustrated by FIG. 7B, the primary channel can be tuned widely as it locates at the center of the low reflection band. As Δ increases up to 1 μm, the resonance peak shifts from κ to 14.5 μm. In view of the individual R₀ plots in FIG. 7C, high diffraction efficiency and well-shaped spectra are also realized for 2D GMR filters.

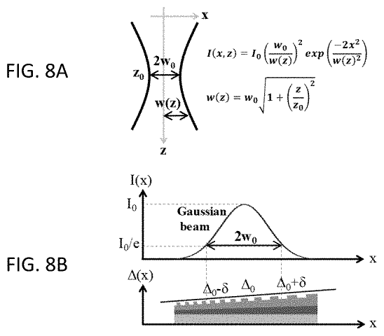

Gratings incorporated into tunable GMR filters in accordance with the present technology can be based on rigorous coupled-wave analysis (RCWA) which is an exact electromagnetic method to model the interaction of incident-light plane waves with periodic structures and thin-film systems. For any given parameter set, diffraction efficiency which represents both reflectance and transmittance is exactly calculated for the periodic structure with incident plane waves. To determine the parameters of the features of an aperiodic (i.e. nonperiodic) grating, repeated RWCA calculations are performed by varying the period (Λ). In application, (i.e., finite grating and Gaussian input beam), the diffraction efficiency decreases and the FWHM (full width at half maximum) broadens relative to the plane-wave case. Further, the efficiency and FWHM can indeed depend on the size of a device and width of the incident Gaussian beam with a given spot size (2w₀), as illustrated in FIG. 8. In some instances, with respect to the present technology, it can be assumed that the filter size will be larger than the Gaussian spot size. Within the Gaussian beam, there is a varying period (AA) and varying thickness of subfilms (ΔDₕ, ΔD_{w}) by the non-periodicity and inhomogeneous subfilms. Therefore, the grating parameters vary with distance away from the center of Gaussian beam. As shown in FIG. 8B, tolerance (±δ) can be defined as a variation of the filter parameters relative to Gaussian beam center. Diffraction efficiency (R₀, T₀) can be effectively estimated by performing sequential plane-wave RCWA calculations across the parametric range spanned by the Gaussian beam at a particular location. These results are then weighted with the Gaussian distribution to form the final result. From this, the resonance position and tunability do not change appreciably for practical beam diameters. For instance, for a ˜50-mm device size and 1 mm Gaussian-beam spot size, approximated reflectance is ˜88% (plane-wave reflectance 100%) and 40 nm FWHM (plane-wave computation yields 36 nm). For higher efficiency, the reflectance can be raised by increasing the device size. The RCWA code can be used as the forward kernel in particle swarm optimization (PSO) codes which assist in determining the device parameter set.

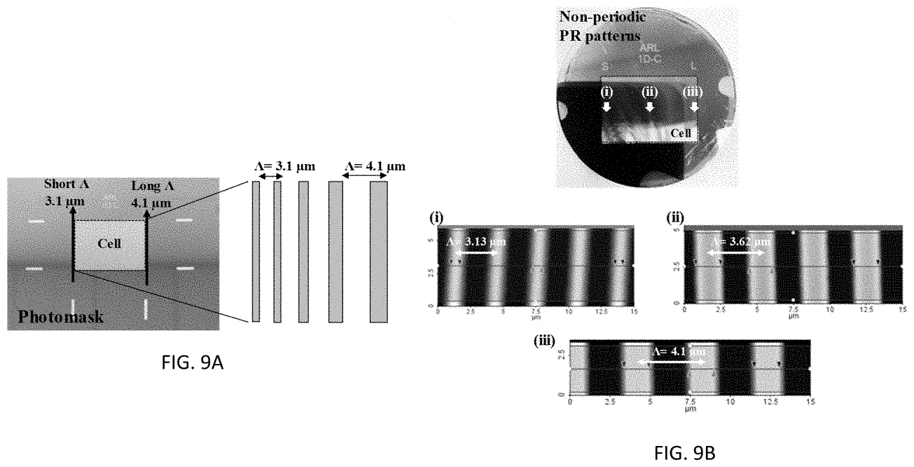

In some embodiments, the fabrication of optical structures, for example filters and resonant gratings, are provided. In some instances, fabrication can include processes such as thin-film deposition, electron-beam patterning, reactive-ion etching, metallization, SEM/AFM inspection, ellipsometric characterization, among others. For aperiodic or nonperiodic gratings, photoresist (PR) patterns can be made by photolithography technology. For the LWIR filters in the 7-14 μm atmospheric window as well as for midwave IR in the 3-5 μm window, the grating period (Λ) can be distributed from approximately 1 to 5 μm which is enabled by customized photo masks. Under consideration of nonperiodic structures, the mask can be designed and fabricated for a specific period and fill factor at each different position. For example, as shown in FIG. 9A, a photomask with nonperiodic line patterns from Λ=3.1 μm to Λ=4.1 μm for operating GMR at 8-10 μm is created. From a created photomask design, a computer-aided design (CAD) file can then be transferred to the metal film via an electron beam writer. With this photomask, non-periodic PR patterns are fabricated as shown in FIG. 9B. AFM images show different periods of the PR patterns at each different position (i)-(iii). Moreover, near-IR and visible filters with similarly concurrently tuned resonance wavelengths and adjacent sidebands are available by laser interference lithography. For Λ<1.5 μm, a laser interferometer is capable of recording the nonperiodic gratings by modification of the mirrors. For example, with a 266-nm laser interferometer capable of recording laterally-extensive periodic patterns in a single shot with periods Λ>200 nm and fill factors F ranging from 0.2 to 0.8 by exposure control, patterning of both 1D and 2D periodic layers can be efficiently accomplished. An interferometer with stepper capability under computer control can also enable arrays of devices on wafers up to 6 inches in diameter to be expeditiously fabricated. Nonperiodic devices are generally also made with imprint methods and molding as well as with electron-beam writing. Master molds can be written with electron beams. Inhomogeneous subfims can be deposited by sputtering or electron-beam deposition system. To change deposition thickness laterally, the deposition thickness is controlled at each different position by a moving mask or by using a triangle-shaped window mask.

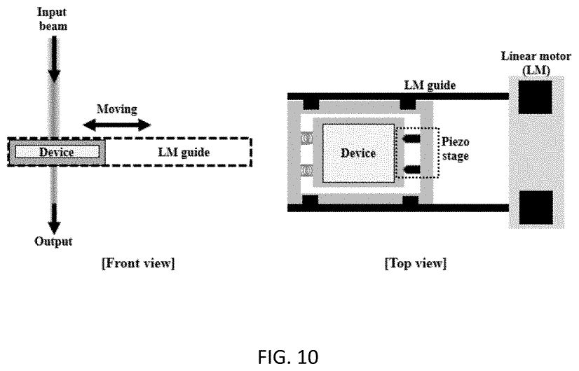

For spectral characterization in a frequency range of interest, matching sources and spectrum analyzers are needed, further including means of polarization control. Devices whose spectra fall within the 1200- to 2400-nm band can be characterized for example with a Yokogawa AQ6375 spectrum analyzer in conjunction with a Koheras Super Continuum illuminating source. Longer-wavelength spectra can be measured with a Fourier-Transform Infrared Spectrometer that covers the ˜1.3- to 28-μm spectral band with ample resolution. Also, tunable quantum cascade lasers (QCL) are capable of precise spectral characterization in the ˜8.2- to 12-μm spectral band with high resolution. Reference samples with known characteristics can be used to ascertain the actual absolute values of reflectance and transmittance. To tune the wavelength of the filters, as illustrated in FIG. 10, relative device position can be controlled relative to the beam position to match any target wavelength. Using linear and piezo motors as well as micrometer stages and drives, the device can reach a given position rapidly and precisely.

Some embodiments described herein are further illustrated in the following non-limiting examples relating to features of optical elements or devices.

The spectral band covering ˜8 to 12 μm is atmospherically transparent and therefore important for terrestrial imaging, day/night situational awareness systems and spectroscopic applications. There is a dearth of tunable filters spanning the band. Here, we propose and demonstrate a new tunable-filter method engaging the fundamental physics of the guided-mode resonance (GMR) effect realized with a nonperiodic lattice. The polarization-dependent filter is fashioned with the one-dimensional Ge grating on ZnSe substrate and interrogated with a ˜1.5 mm Gaussian beam to show clear transmittance nulls. To expand the tuning range, the device parameters are optimized for sequential operation in TM and TE polarization states. The theoretical model exhibits a tunable range exceeding 4 μm thus covering the band fully. In experiment, a prototype device exhibits a spectral range of 8.6-10.0 μm in TM and 9.9-11.7 μm in TE polarization or >3 μm total.

The electromagnetic band from ˜8 to 12 μm covers a region of atmospheric transparency important for major application fields including long-range terrestrial imaging, spectroscopic applications, day/night situational awareness systems, and medical and industrial laser technologies. To utilize this spectral band for such applications, effective components including reflectors, filters, and polarizers must be available. In the visible and near-infrared regions, these and many other functions are realized with conventional multilayer thin-film technology. In the 8-12 μm long-wave infrared (LWIR) region, this method largely fails because quarter-wave films for the LWIR band are 10-20 times thicker than those for the visible region. Hence, levels of stress and absorption that are negligible in the visible region become limiting factors in the manufacturing of multilayer LWIR coatings especially as the layer count grows.

Guided-mode resonance is applied to fashion tunable LWIR filters with single-layer low-loss films as basic building blocks. By designing resonance device grating parameters including period, fill factor and grating depth, a desired spectral response can be tailored. Especially, zero-contrast grating (ZCG) structures, constituting a periodic layer on a matched sublayer, improve parametric stability by effectively supporting lateral leaky modes generated by evanescent diffracted waves. With a focus on the 8-12 μm spectral region, efficient notch filters can be fashioned with germanium-based ZCG architectures. High tunability of a GMR prototype devices can be achieved that are composed of a one-dimensional (1D) aperiodic Ge grating on a zinc selenide (ZnSe) substrate. The GMR peak position can be tuned by mechanically sweeping the device transversely over a beam spot. Current micro-electromechanical systems (MEMS) technology can implement rapid scans.

A wide tuning range of 8.64-11.71 μm in a sequentially scanned device using each TE and TM polarization states may be achieved as described herein. A conceptual design to greatly expand the tuning range to 5-14 μm based on a wedge waveguide underneath a chirped grating is provided. Though this embodiment is expected to provide superb performance with a concurrently tuned channel and sidebands, fabrication of the wedge film is challenging. As an alternative, and as a step along the way, an aperiodic ZCG structure with a single film of constant thickness on a substrate that is straightforward in fabrication is achieved.

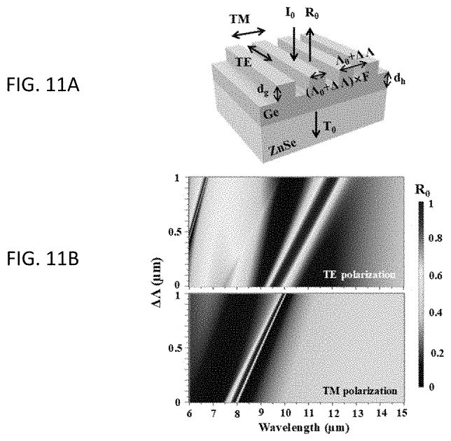

With reference to FIG. 11, design of the tunable resonant filter treating both polarization states are illustrated. As shown in FIG. 11A, a Ge-based grating is laid on the ZnSe substrate in a ZCG architecture which is composed of a grating merged with a homogenous sublayer of the same material. The resulting structure is a waveguide grating with lateral modes occupying both the aperiodic region and the homogeneous film in proportions set by the geometry with the relative aperiodic/homogeneous film thicknesses as a decisive parameter. For device applications in the long wavelength infrared (LWIR) region, germanium (Ge, n_{Ge}=4.1+i0), and zinc selenide (ZnSe, n_{ZnSe}=2.4+i0) are used as low loss materials. Then, a parameter set {Λ, F, d_{g}, dₕ} including the period (Λ), fill factor (F), grating depth (d_{g}) and sublayer thickness (dₕ) is decided. For tunable resonant filters, the grating period is changed as Λ₀+ΔΛ and then simulated as a zeroth-order reflectance (R₀) spectrum by performing a rigorous coupled-wave analysis (RCWA). FIG. 11B shows maps of calculated R₀ spectra under TM (electric field vector perpendicular to the grating grooves) and TE (electric field vector parallel to the grooves) polarization states at normal incidence. The grating parameter set is {Λ=Λ₀ (3.1 μm)+ΔΛ, F=0.32, d_{g}=875 nm, dₕ=675 nm}. As the increment ΔΛ increases from zero to 1 μm, each resonance peak (R₀=1) gradually redshifts because the GMR excites at longer wavelength diffracted by the increased period (Λ₀+ΔΛ). However, the period should slowly change to be locally constant for tenths or hundreds of input wavelength. Thus, we decide cell size 26 mm which provides spatially quasi-constant period, Λ±Δ(<0.6% Λ) for 100λ0. In this design, the GMR peak position is tunable in 7.84-9.96 μm in TM and 9.56-12.04 μm in TE polarization covering the full 8-12 μm window.

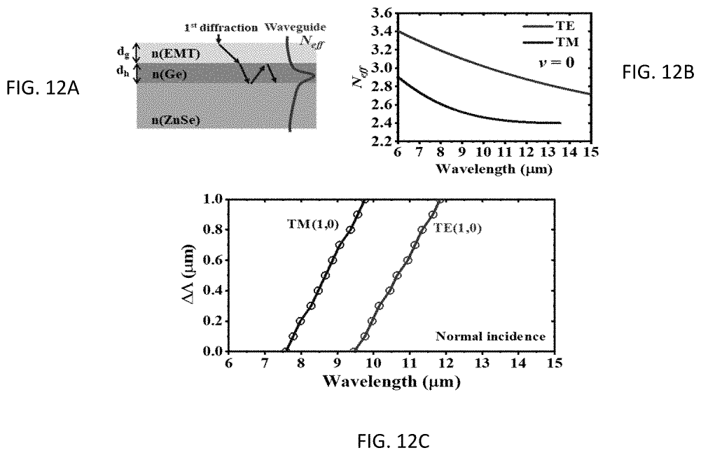

The spectral response can be understood by modeling of an equivalent slab waveguide with effective-medium theory (EMT) as depicted in FIG. 12A. As will be appreciated, under guided-mode resonance (GMR), a perfect reflection occurs at the phase matching condition when a diffracted wave is coupled to leaky waveguide modes. Therefore, the GMR position can be estimated by a simple analytical formula β=2πm/(Λ₀+ΔΛ)=2πN_{eff}(v,λ₀)/λ₀, (Eq. 1) where β, m and N_{eff}(v, λ₀) are the propagation constant, diffraction order and effective refractive index of a slab waveguide as function of mode number (v) and free-space wavelength (λ₀). Equation 1 expresses the coupling condition between diffracted wave (2πm/(Λ₀+ΔΛ)) and waveguide mode (27πN_{eff}/λ₀) where it is assumed that the periods are locally constant. The equivalent slab waveguide is converted from the ZCG architecture of FIG. 11A by homogenization of the grating using zeroth-order effective medium theory.

As illustrated in FIG. 12B, N_{eff} is obtained by solving the slab waveguide with use of a 1D mode solver algorithm [15]. FIG. 2(c) represents the calculated resonance position for both polarizations where we denote TM(1,0) and TE(1,0) when the GMR is excited by the first order (m=1) diffracted wave coupled to the fundamental waveguide mode (v=0). Compared with the rigorously computed reflectance map of FIG. 11B, the modal curves are well matched to the high reflection band in each polarization state. These curves show a linear slope in parallel and they sweep the 8-12 μm range if traversed in sequence.

As an example embodiment, prototype chirped filters are fabricated using photo-lithography processes and dry etching. 2-inch-diameter ZnSe substrates (Crystran Limited, UK) are prepared and 1.55-μm-thick Ge films are deposited via an e-beam evaporation system. To control the thickness, a stable deposition rate of 3.0 Å/sec is selected. Then, positive photoresist (PR, Shipley Microposit S1813) is patterned to implement a 1D grating after UV exposure with an EVG620 mask aligner. For the chirped grating, chromium photomasks are customized which are designed by a non-periodic array of line patterns within a rectangular boundary cell (width: 26 mm, height: 18 mm). From left to right in the cell, the pitch of the lines gradually increases from 3.1 to 4.1 μm to represent the designed device in FIG. 1(a). After development, the Ge film is etched by utilizing reactive-ion etching (RIE) methods with a combination of CHF₃ and SF₆ gases. Finally, after PR removal with a chemical stripper, a prototype device is obtained.

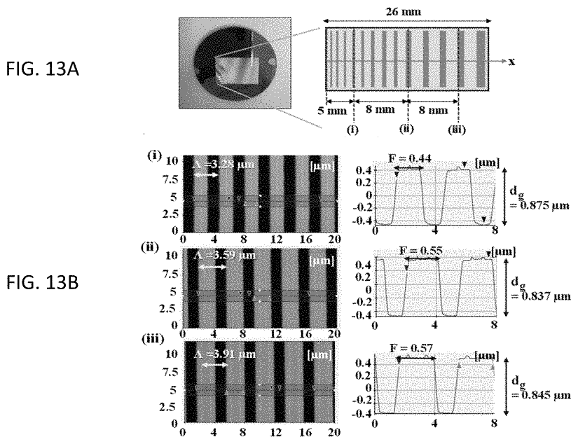

FIG. 13A shows a photograph of a prototype device within a 26 mm×18 mm rectangular cell. The pitch (P) of the lines increases along the x-axis direction. As designed by Λ₀ (3.1 μm)+ΔΛ(0 to 1 μm), the pitch is determined by P(x)=3.1+x/26 mm as a function of lateral position x where the unit is in millimeter. Three representative points are measured at x=(i) 5 mm, (ii) 13 mm and (iii) 18 mm corresponding to P=3.29, 3.6 and 3.79 μm, respectively. FIG. 13B displays atomic force microscope (AFM) images of the prototype device at the points (i)-(iii). With these AFMs, the grating parameter set is measured as (i)={Λ=3.28 μm, F=0.44, d_{g}=875 nm}, (ii)={Λ=3.59 μm, F=0.55, d_{g}=837 nm} and (iii)={Λ=3.91 μm, F=0.57, d_{g}=845 nm} where the dₕ is estimated using 1.55 μm−d_{g}. The measured grating period matches the design pitch well but the F is different and larger than in the original design.

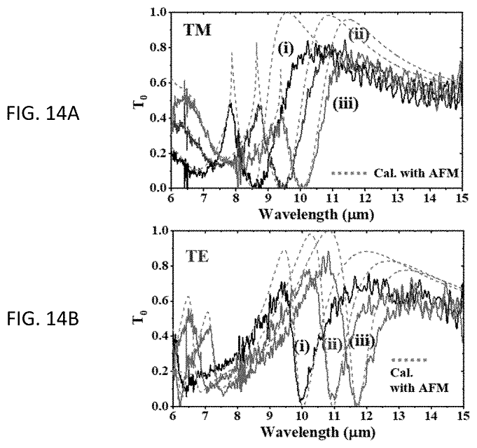

Spectral responses of GMR devices are measured at each point (i)-(iii) in TM and TE polarization. Theoretical results are computed with the measured parameters. Zero-order transmittance (T₀) is measured using a Nicolet iN10 Fourier transform infrared (FTIR) spectrometer with a wire grid polarizer (˜10⁴ extinction ratio) in the beam path. The details of the measurement setup are small variance of incident angle (−0.2°<θ<0.2°). Accordingly, a clipped Gaussian beam with 1.5-mm aperture is used to approximate a collimated input and normal incidence; it resonates fully in the device. Then, FTIR spectrometry data spacing is set to 0.482 cm⁻¹ to take high-resolution spectral efficiency measurements; at this setting there appears some noise on the signals due to associated low FTIR intensity by clipped input beam. As seen in FIGS. 14A and 14B, the resonant peak position and diffraction efficiency agree well with calculated results. However, the line shape is asymmetric due to Fano resonance in non-zero reflection background. This can be improved by antireflection design of grating layer, which leads to symmetrical line shape. In the sidebands, it should be considered that backside reflection (R˜17%) by the substrate degrades the T₀. As the beam position moves to the longer Λ, the resonant peak appears at longer wavelengths. At each point, the peak position/FWHM (full width at half maximum) for TM is {(i) 8.643 μm/1.043 μm, (ii) 9.436 μm/0.918 μm, (iii) 10.025 μm/0.840 μm} and for TE it is {(i) 9.929 μm/0.78 μm, (ii) 10.9 μm/0.738 μm, (iii) 11.71 μm/0.887 μm}. By switching from TM to TE polarization, the device tuning range can be expanded. For TM TE polarization, the device shows fair light rejection with 0.1%˜3.91% of the T₀. It is improved by further reducing the T₀ with multi-stacks of identical gratings.

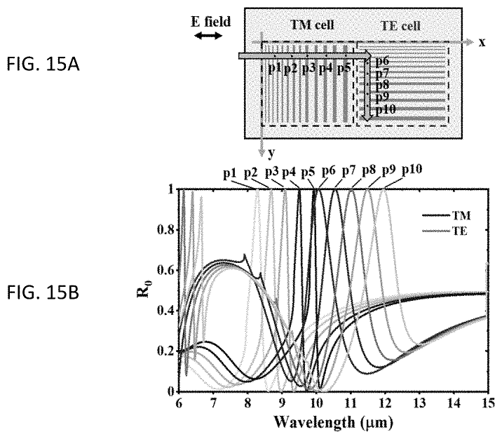

Additionally, feasibility of the tunable notch filter with polarization-extended tuning range can be achieved. In implementation, dual cells in a chip are provided as depicted in FIG. 15A. The parametrically identical cells are arranged orthogonally as seen. Denoted in x-y coordinates, the input beam location can be swept along p1 to p10. For p1-p5, each point is located at pi[x,y]=[3+(i−1)×5 mm, 5 mm]. For p6-p10, the beam locates at pi[x,y]=[30 mm, 3+(i−6)×5 mm]. FIG. 15B shows calculated R₀ spectra at each point p1-p10. Here, the grating parameter set is {Λ=3.1+x (for p1-p5) and y (for p6-p10)/26 mm, F=0.32, d_{g}=875 nm, dₕ=675 nm}. From p1 to p10, the peak position ranges from 8.08 μm to 11.77 μm. This can be realized by translating the chip along the two orthogonal axes.

As described herein, a methodology to implement notch filters that can be MEMS-tuned across wide spectral bands is provided. A single-layer Ge-based ZCG architecture is imbued with a nonperiodic lattice in a 26 mm×18 mm rectangular cell. Quantitative tunability of the spectral response under a varying period is clearly understood by analysis of an equivalent slab-waveguide model supported by RCWA modeling. Applying the polarization dependence of 1D resonant gratings, the tuning range is essentially doubled by first tuning with TM resonant modes and then with TE modes by rotating the cell by 90°. The theoretical model has a tunable range exceeding 4 μm spanning the ˜8 to 12 μm region completely. In experiment, a prototype device offers a range of ˜8.6-11.7 μm thus exceeding 3 μm.

In some further example embodiments, unpolarized resonant notch filters for the 8-12 μm spectral region are provided. The long-wave infrared (LWIR) spectral region spanning ?8 to 12 μm is useful for many scientific and industrial applications. As traditional multilayer film components are not straightforwardly realized at these bands, design, fabrication, and testing of polarization independent bandstop filters is provided based on the guided-mode resonance (GMR) effect. Focusing on the zero-contrast grating architecture, successful fabrication of prototype filters in the Ge-on-ZnSe materials system is achieved. Applying mask-based photolithography and dry etching, photoresist patterns form the desired Ge grating structures. The resulting devices exhibit clean transmittance nulls and acceptably-high sidebands. Moreover, polarization independent notch filtering by assembling two identical GMR filters with gratings oriented orthogonally is achieved. This approach to realize effective GMR elements may be useful for various fields including photonic and optoelectronic devices operating in the LWIR region.

Multilayer dielectric thin films are widely applied to implement metal-free and thus low-loss filters, polarizers, and reflectors for incorporation in various common optical systems. These devices typically consist of stacks of homogeneous layers deposited with precise thicknesses and tight control of index of refraction and absorption. In many cases, a large number of layers, perhaps ˜10-100, may be needed to create the spectral, polarization, and angular attributes required for a particular application. Commonly, quarter-wave or half-wave film thickness is needed to accomplish the design objectives. In the visible or near-infrared spectral regions, ordinary deposition methods, albeit slow, work well. In contrast, in the mid-to-long IR wavelength bands where a quarter-wave layer measures a couple of micrometers, multilayer thin-film deposition becomes impractical on account of the excessive time required to attain needed thicknesses. Thus, alternate methods must be found to provide optical component technology for these spectral regions.

Here, single-film guided-mode resonant (GMR) prototype devices are provided as a feasibility proof of efficient unpolarized notch filters in the 8-12 μm spectral band. The periodic films applied exhibit resonance effects that originate in quasi-guided, or leaky, waveguide modes. With thickness and period on the order of the wavelength, these compact elements yield versatile photonic spectra and surface-localized energy states. Using powerful electromagnetic design methods, the spectral bands of these subwavelength resonant leaky-mode elements can be engineered to achieve photonic devices with desired practical attributes.

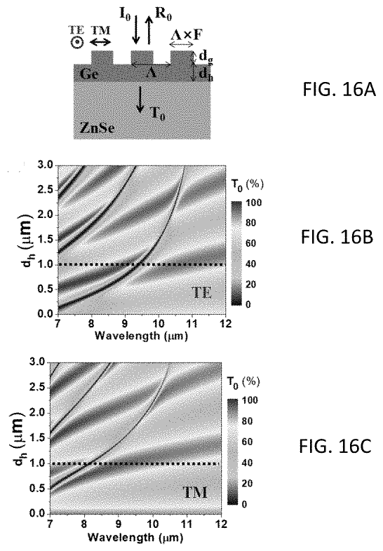

To realize GMR notch filters, s zero-contrast grating (ZCG) architecture is used which consists of a grating and a sublayer with the same refractive index. In the ZCG, the sublayer effectively guides lateral Bloch modes coupled by evanescent diffraction orders. Moreover, it stabilizes the local resonant fields and contributes to parametric stability in fabrication. Thus, under thickness variation, flexible spectral response is attainable. FIG. 16A presents a one-dimensional (1D) germanium (Ge) based ZCG on a zinc selenide (ZnSe) substrate where Λ, F, d_{g} and dₕ denote grating period, fill factor, grating depth, and sublayer thickness. To achieve high diffraction efficiency, we choose Ge and ZnSe because these are transparent, lossless dielectric materials with refractive indices of 4 and 2.4 in the spectral region of interest. Then, with this model, the grating parameter set (Λ, F, d_{g}, dₕ) is determined by performing rigorous coupled-wave analysis (RCWA). At normal incidence, the spectral response is calculated with the input plane wave transverse-electric (TE; electric field vector parallel to the grooves) polarized and in the TM-polarization state (e-field perpendicular to the grooves). As shown in FIGS. 16B and 16C, the calculated zeroth-order transmittance (T₀) spectra of the ZCG are displayed as a function of dₕ in contour color maps. Here, according to the RCWA determination, the grating parameter set (Λ=2.85 μm, F=0.4, d_{g}=0.5 μm) is fixed. As dₕ varies up to 3 μm, the GMR reflectance peak position (T₀=0) and background transmission change continuously. As the sublayer becomes thicker, the GMR peak position moves to a longer wavelength consistent with classic waveguide theory. In parallel, this increase of the homogeneous film thickness repeats constructive and destructive interference, thus leading to iterative background transmission in a Fabry-Perot sense. At dₕ=1 μm, near-optimal T₀ spectrum for IR notch filters is found with TE and TM transmittance nulls located at 9.38 μm and 8.132 μm, respectively, while being surrounded by high transmission bands.

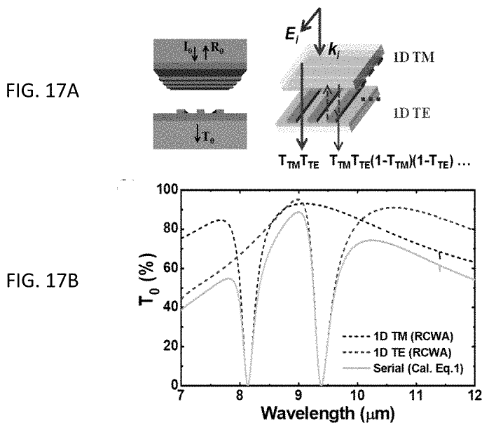

Aiming for a polarization independent operation with the determined 1D grating, serial device modules are utilized for wideband reflectors. Unlike general 2D grating systems, this method enables polarization independent operation by assembling two linear gratings sequentially. FIG. 17A illustrates the serial structure. Two identical 1D ZCG devices are orthogonally assembled to have the same output T₀ under both TE and TM polarization. This can be explained by total external transmittance (T) considering subsequent TM and TE transmittance (T™ and T_{TE}) as depicted in FIG. 17A. Using a similar method as previously described, T is estimated by formula:

$$\begin{matrix}T = {T}_{T M} {T}_{T E} {\sum }_{n = 0}^{∞} {[ ( 1 - {T}_{T M} ) ( 1 - {T}_{T E} ) ]}^{n} \\ = \frac{{T}_{T M} {T}_{T E}}{[ 1 - ( 1 - {T}_{T M} ) ( 1 - {T}_{T E} ) ]}\end{matrix}$$

FIG. 17B shows the calculated results of the serial device compared with the T_{TE} and T_{TM} of the 1D ZCG. Two GMR peaks in the serial device retain the position and efficiency of each 1D ZCG. However, the sidebands are somewhat degraded because the external transmittance T decreases by passing through two gratings. Indeed, the product of T_{TE} and T_{TM} is dominant in determining T even though multiple internal transmission enhances T. Therefore, to improve the sidebands, both the T_{TE} and T_{TM} should be high in same spectral band.

Experimentally, 1 inch diameter and 1 mm thick ZnSe substrates from Crystran Ltd. (Dorcet, UK) were prepared. To avoid chemical damage from acid solutions, the substrates were immersed in an ultrasonic acetone bath for 20 minutes and an ultrasonic isopropyl alcohol (IPA) bath for 20 minutes. Next, the substrates were rinsed with deionized water and dried with nitrogen gas. After cleaning, a 1.5-μm-thick Ge film was deposited by e-beam evaporation on the substrate. During the processing, a deposition rate of 3.0 Å/sec was maintained and the deposition thickness was controlled by a quartz crystal thickness monitor. To prevent oxidation of the Ge surface as well as to promote adhesion of photoresist (PR), a 10-nm silicon (Si) layer was then deposited on the Ge film by a sputtering system. The thickness and refractive index of each film were measured and confirmed by utilizing a spectroscopic ellipsometer. Based on measurements, the imaginary part of the Ge index was estimated to be ˜0.001 thus contributing negligible absorption.

Positive PR (Shipley Microposit S1813) was then spin-coated onto the sample for 60 seconds at 4000 rpm. After that, edge-bead removal solvent was dropped onto the outside of the PR-coated substrate and spun for 30 seconds at 3000 rpm. This was done because an undesired edge bead could form during spin-coating that, left alone, could cause diffractive distortion and damage the PR pattern. Following edge-bead removal, the PR coated sample was soft baked at 115° C. for 60 seconds on a hot plate. Then, in order to create the 1D grating structure in the PR layer, contact photolithography was applied with an EVG620 mask aligner. The chromium photomask used for the exposure was obtained from Photronics, Inc. (Allen, Tex.). After exposure, the samples were baked at 115° C. for 60 seconds, and then developed in Microposit MF-321. Using a reactive-ion etching (ME) machine, the PR grating pattern was transferred onto the Ge film with a combination of CHF₃ and SF₆ gases. Using the proper etch recipe for the PR/Ge layer combination, a selectivity of ˜1:1.9 was obtained and the Ge etch rate was 175 nm/min. The PR residual layer was removed by immersing the etched sample in a PR stripper solution placed in the ultrasonic cleaner. After PR removal, the single-layer Ge filter was obtained. Thus, the etch depth can be controlled to ˜±2% therefore avoiding the use of an etch-stop layer.

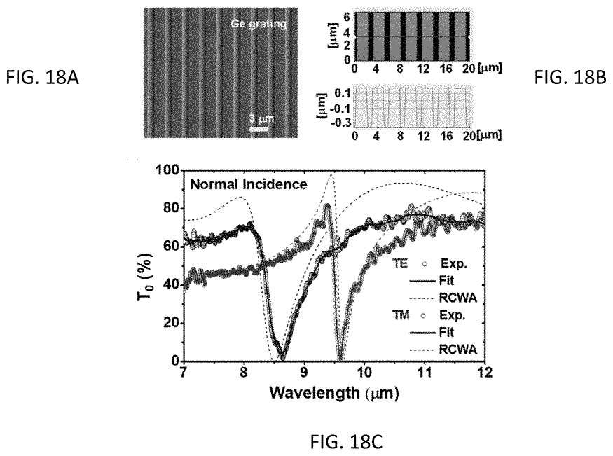

FIG. 18A shows a top view of the fabricated GMR filter obtained with a scanning electron microscope (SEM), indicating a straight and uniform Ge-based line grating structure. FIG. 18B shows atomic force microscope (AFM) images of the GMR filter. With these images, the grating parameter set is measured as (Λ=2.85 μm, F=0.65, d_{g}=0.535 μm, dₕ=1 μm). The F is somewhat larger than in the original device design due to experimental inaccuracies in the photolithography and dry etching processing. FIG. 18C shows the experimental and theoretical (using measured parameters) spectral response of the GMR filter for both TE and TM polarizations. The spectra of the fabricated GMR filter were measured using a Nicolet iN10 Fourier transform infrared (FTIR) spectrometer with iZ10 transmission measurement attachment. A 10,000:1 extinction ratio wire-grid linear polarizer was used to set the polarization state. To quantify the spectral response of the resonant grating, the measured spectrum was normalized by the intensity of the input beam. The measured wavelength range is from 7 to 12 μm in 0.011 μm steps. As seen in these curves, TE and TM peaks are located at 9.6 μm and 8.64 μm with 0.42 μm and 0.657 μm FWHM (i.e., full width at half maximum) respectively, with high transmission side bands. In the sidebands, T₀ is degraded by a significant back side (substrate) reflection of R˜17%. In view of this reflection loss, not compensated in the experimental data, the experimental curves and the theoretical spectra are in good agreement, which indicates the device dimensions obtained by SEM and AFM measurements are accurate.

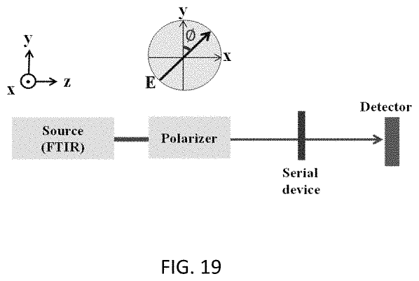

FIG. 19 illustrates the experimental setup for measuring the T₀ spectra of the serial GMR device. For verification of polarization independence, we prepared the combined serial device by assembling two individual 1D GMR devices with gratings oriented orthogonally and then measured the spectral response by varying the polarization direction. To define the polarization direction or angle, we set the zero angle along the y-axis. As the angle increases, the polarization direction is rotated clockwise.

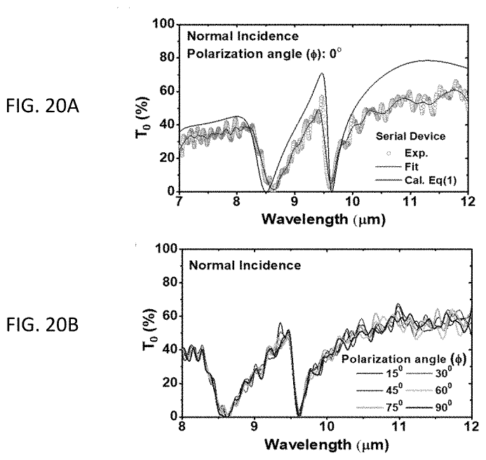

Prior to the investigation of the polarization independent T₀ spectra, we analyze the spectrum at the zero angle of polarization as shown in FIG. 20A. As in FIG. 18C, the measured T₀ is reduced by backside reflections at each substrate. This can be improved by application of antireflection coatings as planned in future experiments. Comparing to the GMR peaks of TM and TE polarization in FIG. 3(c), the serial device possesses similar null positions and efficiency. In addition, the spectrum is well matched to analytical calculation using Eq. (1). In FIG. 20B we can see that this device preserves the two GMR null transmission positions and sidebands even while changing the polarization angle.

In summary, we theoretically and experimentally demonstrate notch GMR filters for the 8-12 μm spectral region by employing Ge-based ZCG design. In the ZCG architecture, the sublayer thickness is an important parameter to control GMR peak position and sideband transmission. With specified sublayer thickness, we theoretically determined the spectral response of our notch filters. Also, we successfully fabricated the Ge-based ZCG devices on ZnSe substrates. Applying pertinent photolithography and RIE etching processes, the PR patterns were transferred to the desired Ge grating structures. Moreover, we verify polarization independent notch filter by assembling two identical GMR filters with gratings oriented orthogonally. Based on the experimental result, the serial device shows reliable operation as an unpolarized notch filter. These results will be useful for various fields and applications, including photonic and optoelectronic devices operating in the LWIR region.

In some even further embodiments, other resonant filters with concurrently tuned central wavelengths and sidebands are provided. Tunable infrared (IR) filters are important for various optical and optoelectronic systems. Ideally, such filters should span wide spectral ranges while retaining constant performance. Here, as a fundamental approach, we theoretically treat tunable resonant filters and realize favorable spectral profiles. Implementing a chirped zero-contrast grating on wedged sublayers, we design the resonant tunable filter for operation in the ˜5-14 μm band. To clarify the root causes of the physical processes enabling the observed performance, attendant resonance modal processes and background reflection behavior are analyzed in detail by equivalent models as well as by rigorous electromagnetic models. The key innovative contribution is that it enables efficient filters with simultaneously tuned operational wavelengths and sidebands.

Ideal tunable optical filters provide a continuum of well-shaped spectra with variable central wavelengths implementable with a single device. They are useful in a host of applications in sensors, imaging and spectroscopy systems. For specific purposes to suit the applications, these devices have been developed by different technologies such as liquid crystals, acousto-optic filters, linear-variable elements, and angle-tunable filters. Among them, we focus here on thin-film resonant filters, which consist of a non-homogenous layer without multi-stacks. We theoretically demonstrate highly tunable filters utilizing guided-mode resonance (GMR) operating in a wide spectral range of ˜5-14 μm with practical sideband levels. GMR has been considered a promising physical phenomenon for various applications including reflectors, narrow bandpass filters, and polarizers. The resonant effects in the periodic subwavelength structure originate in leaky waveguide modes that are excited when coupled to evanescent diffraction orders. Therefore, specific photonic spectra can be tailored by engineering the grating parameters and the refractive index profile. Particularly, we have implemented a constituent grating which is structured by merging the discrete grating to a homogenous layer composed of the same material. This configuration is “zero-contrast grating (ZCG)” and can be implemented in wideband reflectors and bandpass filters. In the ZCG, the grating layer with the sublayer (e.g., the homogenous or inhomogenous layer underneath the grating) effectively supports guided lateral Bloch modes. The sublayer has the effect of stabilizing the spectra yielding robust devices in view of parametric variations.

In the ZCG-on-waveguide structure, the thicknesses of the sublayer and the waveguide are key parameters by which to adjust the proper background of the spectral response to set the sideband levels. To control the GMR location and thus the central filter wavelength, we use chirped gratings. To tune the sidebands, wedged subfilms are deployed. Challenging at first glance, this combination is ultimately realizable.

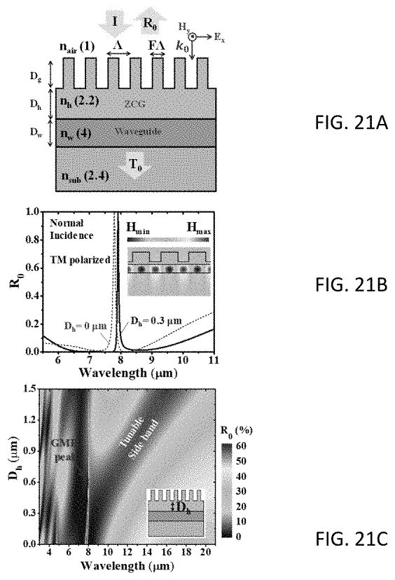

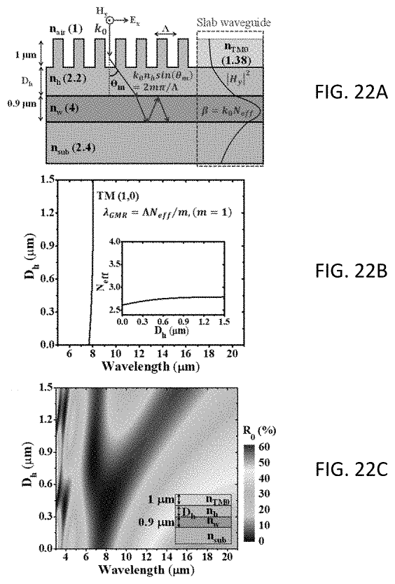

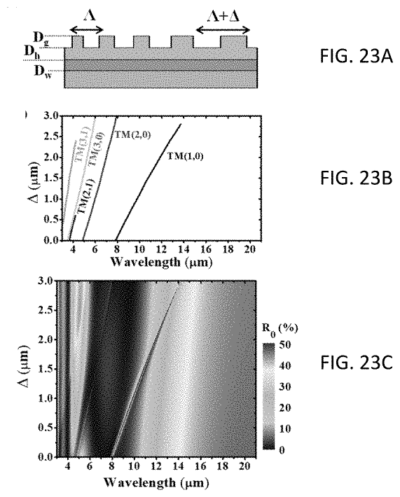

FIG. 21A presents a one-dimensional (1D) ZCG on a waveguide structure. With a relatively low refractive index, the ZCG plays two important roles. First, the grating diffractively couples the input light to the waveguide forming a lateral guided mode. Here, the period predominantly sets the spectral GMR location. Secondly, the sublayer of the ZCG suppresses the background reflection as a buffer layer which relieves the large difference of refractive index between the grating and the waveguide. However, for the designs presented, the sublayer does not significantly influence the GMR location. These roles are discussed further with the calculation and results in FIGS. 22 and 23. A grating parameter set can be defined as {Λ=period, F=fill factor, D_{g}=grating depth, Dₕ=sublayer thickness, D_{w}=waveguide thickness}. For high diffraction efficiency operating in the long wavelength infrared (LWIR) region, we choose ZnS (n_{ZnS}=2.2), Ge (n_{Ge}=4), and ZnSe (n_{ZnSe}=2.4) as low loss materials. These indices are dispersive with absorption {ñ(λ)=n(λ)+ik(λ)} in the LWIR region. Here, within focused region of 3-20 μm, we approximate them as constant and lossless consistent with previous experiments. Then, we optimize the parameter set using rigorous coupled-wave analysis (RCWA). The spectral response is calculated at normal incidence with a TM-polarization state (E-field perpendicular to the grooves) as noted in FIG. 21A. FIG. 21B shows the optimized R₀ spectra for the narrowband reflection filter. For the grating parameter set {Λ=2.9 μm, F=0.6, D_{g}=1 μm, Dₕ=0.3 μm, D_{w}=0.9 μm}, a TM resonance peak (R₀=100%) with a narrow band (FWHM=48 nm) locates at 7.91 μm. For R₀<5%, the sideband is distributed from 5.96 μm to 9.65 μm. Comparing the R₀ spectrum at Dₕ=0 μm, it is clear that the sublayer aids in suppressing the sidebands. In a view of the magnetic field (H) distribution, it can be ascertained that the GMR is generated by first-order diffraction coupled to the waveguide. In FIG. 21C, the Dₕ dependent R₀ spectra are featured in a color contour map. As Dₕ increases, the GMR peak position moves to slightly longer wavelengths. In contrast, the low reflection region becomes gradually wider and red-shifted with a split. This trend of background reflection is suitable for flexible control of the sidebands of the tunable filter. However, the GMR peak position does not follow along to the center of sideband, which can be resolved by variation of the grating period via chirping.

To understand the spectral response of FIG. 21C, the equivalent slab waveguide and modal processes are analyzed as illustrated in FIG. 22A. For the slab waveguide, the refractive index of the top layer is estimated by zeroth-order effective medium theory in TM mode (n_{TM0}=1.38). Under normal incidence, the light passes through the ZCG with diffraction angle (θₘ) as k₀nₕ sin(θₘ)=2mπ/Λ which is a phase matching condition. Therefore, the longitudinal component of wave vector in each layer is 2mπ/Λ. When it equals to the propagation constant of waveguide (i.e., 2mπ/Λ=β=k₀N_{eff}), the diffracted wave can be coupled to a waveguide mode. For the equivalent multilayer slab waveguide, the effective index of the guided mode (N_{eff}) and propagation constant (β) are obtained by a mode solver for multilayered media. FIG. 22B shows the calculated GMR peak position as a function of the Dₕ which is well matched to the RCWA-computed GMR location in FIG. 21C. Here, the mode is labeled as TM(m,n) when the GMR forms at the mth diffraction coupled to the nth guided mode. In this case, only TM(1,0) is generated in this spectral range. Even though the Dₕ increases substantially, the TM(1,0) position is minimally varied. In a view of the inset, it is explained by the fact that the N_{eff} varies slowly due to the low refractive index of the sublayer Dₕ. Thus, the λ_{GMR} shifts only a little. In contrast, the value of Dₕ substantially influences the background reflection. FIG. 22C shows the R₀ spectra of the corresponding multilayer where the top layer is homogenized with zero-order effective refractive index (n_{TM0}=1.38) to eliminate the GMR. The spectral characteristic is comparable to the background reflectance of FIG. 21C. As the Dₕ increases, the low reflection band expands and moves to the longer wavelengths because the buffer layer (n=2.2) between the top layer (n=1.38) and the waveguide (n=4) relieves the index difference while changing the spectral region of destructive interference.

According to the formula (2mπ/Λ=k₀N_{eff}), it can be determined that a chirped grating is an efficient way to tune the GMR position. FIG. 23A illustrates a conceptual chirped grating with variation (Δ) of period. In example cases, the grating period can be tuned by laterally transferring the device relative to an illuminating beam. FIG. 23B shows the modal curves associated with the chirped grating where the grating parameter set is {Λ=2.9 μm+Δ, F=0.6, D_{g}=1 μm, Dₕ=0.3 μm, D_{w}=0.9 μm}. As Δ increases, five GMR modes appear in the spectral band shown and move to longer wavelengths. In particular, the TM(1,0) mode, the only one that experiences subwavelength conditions, shifts quickly away from the other GMR modes, which is desirable to avoid interference from these channels which would generate undesired reflection peaks. In FIG. 23C, this trend is also seen in the results of RCWA calculation for the same structure. Simulating the R₀ spectra by varying the A with corresponding grating parameter set is repeated. As expected via the modal curve in FIG. 23B, the primary channel appears separately from the other channels and is tuned by the variation of the period. However, the chirped grating does not affect the background reflection. To implement some tunable filters, therefore, concomitantly moving the sidebands to effectively surround the resonance spectral peak is achieved.

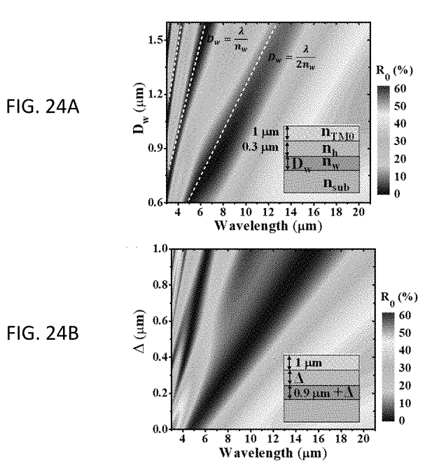

In some low tunable sidebands are determined. As shown in FIG. 24A, the sideband moves to longer wavelengths while increasing the thickness of the waveguide (D_{w}). In fact, the low reflection region is mainly formed by destructive interference. In this case, the destructive interference condition is given by 2n_{w} D_{w}=qλ where q is an integer. The condition is well matched to the tunable sidebands as represented by the white dashed lines. To further expand the bandwidth, we apply the variation (Δ) to D_{w} and Dₕ at the same time. FIG. 24B represents the corresponding result. When Δ increases, the low reflectance region expands and red shifts. This is attributed primarily to the increase of the buffer layer thickness.

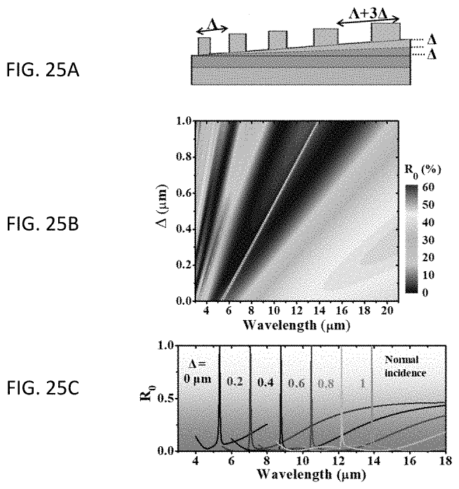

Highly tunable GMR filters with a chirped ZCG on a wedged structure are achieved as shown in FIG. 25A. To match the tunable position of the GMR peak (λ_{GMR}) and the center of the sideband (λ_{side}), we consider each shift rate (Δλ_{GMR}/Δ, Δλ_{side}/Δ) per the variation (Δ). From FIG. 23C and FIG. 24B, the shift rates of the chirped grating and wedged structure are found as 2.11 and 7.26, respectively, which means that λ_{side} tunes 3.43 times faster than λ_{GMR} for the same variation. Considering the GMR peak shift affected by the variation in the wedged structure, we decide on a factor 3 between the chirped grating and wedged structure and then configured the grating parameter set as {Λ=2 μm+3Δ, F=0.6, D_{g}=1 μm, Dₕ=Δ, D_{w}=0.9 μm+Δ}. Here, refraction of the wedge structure is ignored because the angle of incidence is close to zero (i.e., θ_{inc}˜0.001° for Δ=1 μm in 2×2 mm² of device size). FIG. 25B presents the R₀ map of the structure. Again, RCWA calculation is repeated with varying the Δ to the optimal grating parameter set. It shows that the primary channel locates at the center of the sideband. As Δ increases up to 1 μm, the GMR peak gradually shifts from 5.3 to 14 μm. In view of the individual R₀ plots in FIG. 25C, this indicates the promising result that tunable filters with this architecture can attain high diffraction efficiency with well-shaped spectra. When Δ=0 μm, the sidebands are high, owing to the high-contrast grating without a sublayer. Above the Δ=0.2 μm level, the sidebands retain low reflection mediated by the buffer layer in the ZCG.

Thus highly tunable GMR filters are achieved by designing a chirped ZCG on wedged subfilms, which provides a wide tunable spectral range of ˜5-14 μm with low reflection sidebands. Previously, as the other approach for the tunable filters, angular dependent compact GMR notch filters based on a single ZCG film are achieved, which is necessary for IR imaging or sensing devices. By mechanically tilting the device up to 23°, the peak position was split and tuned from 9.3 μm down to 8.5 μm and up to 10.2 μm. For many applications, however, wider tunable spectral ranges as well as lowered sidebands are needed. As a fundamental approach to achieve this aim, a chirped ZCG on a wedged sublayer and a similarly wedged waveguide film is provided. To thoroughly grasp the root causes of the spectral response, the resonance modal processes and background reflection behavior are analyzed in detail by equivalent models as well as by rigorous electromagnetic models. Thereby, the contributions and influence of each building block in the device are understood clearly. This will be applied for various type of ZCG on wedge structure with different materials considering spectral region. Not only TM polarization, this concept can be applied for the narrow bandpass filters with TE modes. The resultant design can be experimentally demonstrated by developing appropriate fabrication processes. Indeed, there have been several reports on design and fabrication methods for chirped gratings and wedged layers at short wavelengths. Many different arrangements of the various components and/or steps depicted and described, as well as those not shown, are possible without departing from the scope of the claims below. Embodiments of the present technology have been described with the intent to be illustrative rather than restrictive. Alternative embodiments will become apparent from reference to this disclosure. Alternative means of implementing the aforementioned can be completed without departing from the scope of the claims below. Certain features and subcombinations are of utility and can be employed without reference to other features and subcombinations and are contemplated within the scope of the claims.

1. A tunable optical filter comprising:
a resonant grating layer having an aperiodic pattern;
an optional sublayer;
a waveguide layer; and
a substrate layer,
wherein at least one of the waveguide layer and the sublayer, when present, is inhomogenous.

2. The tunable optical filter of claim 1, wherein a first band of electromagnetic radiation is transmitted through or reflected by the tunable optical filter.

3. The tunable optical filter of claim 2, wherein the first band of electromagnetic radiation has >90% transmittance or reflectance and adjacent bands to the first band of electromagnetic radiation have <10% transmittance or reflectance, respectively.

4. The optical filter of claim 1, wherein the aperiodic pattern is a one-dimensional aperiodic pattern.

5. The optical filter of claim 1, wherein the aperiodic pattern is a two-dimensional aperiodic pattern.

6. The optical filter of claim 1, further comprising an antireflection coating applied to a surface of the substrate.

7. The optical filter of claim 1, wherein the resonant grating layer is formed from Si₃N₄, TiO₂, ZnO, ZnSe, ZnS, Si, Ge, epoxy, or fiberglass.

8. The optical filter of claim 1, wherein the optional sublayer is formed from Si₃N₄, TiO₂, ZnO, ZnSe, ZnS, Si, or Ge.

9. The optical filter of claim 1, wherein the waveguide layer is formed from Si₃N₄, TiO₂, ZnO, ZnSe, ZnS, Si, or Ge.

10. The optical filter of claim 1, wherein the substrate is formed from a chalcogenide glass, ZnSe, ZnS, Si, Ge, silica, or quartz.

11. The optical filter of claim 1, wherein the optional sublayer is present.

12. The optical filter of claim 1, wherein the optional sublayer is absent.

13. The optical filter of claim 1, wherein at least one of the waveguide layer and the sublayer, when present, is an inhomogenous layer.

14. The optical filter of claim 13, wherein the inhomogenous layer has a thickness gradient along the length of the top surface of the optical filter.

15. The optical filter of claim 13, wherein the inhomogenous layer has a first thickness gradient along the length of the top surface of the optical filter and a second thickness gradient along the width of the top surface of the optical filter.

16. A method of fabricating a tunable optical filter, comprising:
determining an aperiodic grating pattern for a resonant grating layer;
determining a thickness gradient for a waveguide layer and optionally a thickness gradient for an optional grating sublayer;
depositing the waveguide layer onto a substrate, corresponding to the determined thickness of the waveguide layer;
depositing a thin film layer onto the waveguide layer; and
generating the resonant grating layer in at least a portion of the thin film layer, corresponding to the determined aperiodic grating pattern.

17. The method of claim 16, wherein generating the resonant grating layer forms the resonant grating layer and the optional grating sublayer.

18. The method of claim 16, wherein generating the resonant grating layer forms the resonant grating layer directly on top of the waveguide layer and the optional sublayer is not formed.

19. The method of claim 16, wherein:
determining the aperiodic grating pattern for the resonant grating layer and determining the thickness gradient for the waveguide layer and optionally the thickness gradient for the optional grating sublayer comprises selecting a specified wavelength transmission or reflectance band.

20. A method of transmitting and/or reflecting light, comprising:
receiving an incident electromagnetic wave at the tunable optical filter of claim 1;
wherein a first band of the incident electromagnetic radiation is transmitted through or reflected by the tunable optical filter; and
adjacent bands to the first band of electromagnetic radiation have <10% transmittance or reflectance, respectively.
